(19) United States
(12) Patent Application Publication
(10) Pub. No.: US 2025/0364365 A1
(43) Pub. Date: Nov. 27, 2025

(54) COOLING ARRANGEMENT FOR A BACKSIDE POWER DELIVERY NETWORK

(71) Applicant: Purdue Research Foundation, West Lafayette, IN (US)

(72) Inventor: Tiwei Wei, Lafayette, IN (US)

(73) Assignee: Purdue Research Foundation, West Lafayette, IN (US)

(21) Appl. No.: 19/217,619

(22) Filed: May 23, 2025

Related U.S. Application Data
(60) Provisional application No. 63/651,431, filed on May 24, 2024.

(51) Int. Cl. H01L 23/467; H01L 23/50

(52) U.S. Cl. CPC H01L 23/467; H01L 23/50

(57) ABSTRACT

An integrated circuit includes a transistor layer, a backside power delivery network having a buried power rail and a plurality of backside metal layers, a power source electrically connected to the buried power rail by electrical connections in the plurality of backside metal layers, and a cooling arrangement defined at least partially in the plurality of backside metal layers. The cooling arrangement is formed of a plurality of inlet channels, a plurality of outlet channels, and a plurality of cooling channels, wherein each of the plurality of inlet channels is fluidly connected to a plurality of cooling channels, and each of the plurality of cooling channels is fluidly connected to the plurality of outlet channels.

This application claims priority to U.S. Provisional Application Ser. No. 63/651,431 entitled “Thermal Mitigation for Backside Power Delivery Network” filed May 24, 2024, the disclosure of which is incorporated herein by reference in its entirety.

### FIELD

This disclosure relates generally to integrated circuits, and, more particularly, to integrated circuits having a backside power delivery network.

### BACKGROUND

In the semiconductor industry, improvements in chip power, performance, and area (PPA), including CPUs and memory components like static random access memory (SRAM) and dynamic random access memory (DRAM) have traditionally been driven by the front end of line (FEOL) process. As semiconductor technology approaches its physical limits, the back end of line (BEOL), middle of line (MOL), and packaging phases have gained importance in shaping and enhancing chip and system PPA. The implementation of 3D system integration technology has notably improved SRAM-on-Logic system PPA by optimizing memory-to-logic connections. Additionally, a backside interconnect, positioned beneath the substrate, offers a valuable complement to traditional chip BEOL. This approach is particularly beneficial for advanced technology nodes below 2 nm, such as CFET (Complementary Field Effect Transistor), and supports both 2D and 3D chip configurations.

A backside power delivery network (BSPDN) is an advanced architecture in which power delivery to the active devices on a semiconductor die is routed through the backside of the substrate, rather than the conventional frontside routing through metal interconnect layers. This structure is achieved by thinning the silicon substrate and implementing through-silicon vias (TSVs) or other conductive pathways that allow direct electrical connections from the backside of the die to the power distribution network.

The BSPDN architecture enhances power delivery efficiency by reducing resistive losses, minimizing voltage drop, and reduces signal routing congestion on the frontside of the die. Moreover, the BSPDN facilitates the routing of global signals like SRAM macro addresses, data signals, and other lengthy logic signals (e.g., clock tree) beneath the substrate, enhancing integrated circuit (IC) performance and power efficiency.

However, using a BSPDN can cause thermal issues with the transistor arrangement. In particular, the BEOL stack and bonding oxide increase thermal resistance toward the top of the BSPDN, which impedes the effective removal of heat generated at the active transistors. Further, the thinning of the substrate, made possible by routing the power connections to the back side, results in increased horizontal thermal resistance and consequently decreased lateral heat spreading, leading to higher extreme temperature and temperature nonuniformity due to hot spots. What is needed, therefore, is an integrated circuit configuration with a BSPDN that effectively manages heat buildup.

### SUMMARY

In one embodiment, an integrated circuit includes a transistor layer, a backside power delivery network having a buried power rail and a plurality of backside metal layers, a power source electrically connected to the buried power rail by electrical connections in the plurality of backside metal layers, and a cooling arrangement defined at least partially in the plurality of backside metal layers. The cooling arrangement is formed of a plurality of inlet channels, a plurality of outlet channels, and a plurality of cooling channels, wherein each of the plurality of inlet channels is fluidly connected to a plurality of cooling channels, and each of the plurality of cooling channels is fluidly connected to the plurality of outlet channels.

In another embodiment, a method of fabricating a cooling arrangement of an integrated circuit includes forming a plurality of cooling channels in at least one backside metal layer of a backside power delivery network of the integrated circuit and forming a plurality of inlet and outlet channels, each of which is connected to the plurality of cooling channels.

In a further embodiment, a cooling arrangement includes a plurality of inlet channels, a plurality of outlet channels, and a plurality of cooling channels formed at least partially in a plurality of backside metal layers of a backside power delivery network of an integrated circuit. Each of the plurality of inlet channels is fluidly connected to a plurality of cooling channels, and each of the plurality of cooling channels is fluidly connected to the plurality of outlet channels.

### BRIEF DESCRIPTION OF THE DRAWINGS

FIG. 1 is a schematic cross-sectional view of an integrated circuit having a backside power delivery network with a cooling arrangement according to the disclosure.

FIG. 2 is a side perspective view of the integrated circuit and cooling arrangement of FIG. 1.

FIG. 3 is a side perspective view of the cooling arrangement of FIG. 1 with the structures of the BSM3 and manifold layers simplified for clarity.

FIG. 4 is a detail view of the cooling arrangement of FIG. 3.

FIG. 5 is a process diagram of a method of fabricating the cooling arrangement of FIG. 1.

FIG. 6A is a side cross-sectional view of a BSM layer having a plurality of metal structures embedded in a dielectric material.

FIG. 6B is a side cross-sectional view of the BSM layer of FIG. 6A after etching the dielectric material.

FIG. 6C is a side cross-sectional view of the BSM layer of FIG. 6B after applying a barrier protection layer and thermally conductive layer.

FIG. 6D is a side cross-sectional view of the BSM layer of FIG. 6C after applying a further dielectric layer over the barrier layer and thermally conductive layer, forming cooling channels.

FIG. 6E is a side cross-sectional view of the BSM layer of FIG. 6D after etching the further dielectric layer, forming channel connections and inlet and outlet channels.

FIG. 6F is a side cross-sectional view of the BSM layer of FIG. 6E after enclosing the inlet and outlet channels.

### DETAILED DESCRIPTION

For the purposes of promoting an understanding of the principles of the embodiments described herein, reference is now made to the drawings and descriptions in the following written specification. No limitation to the scope of the subject matter is intended by the references. This disclosure also includes any alterations and modifications to the illustrated embodiments and includes further applications of the principles of the described embodiments as would normally occur to one skilled in the art to which this document pertains.

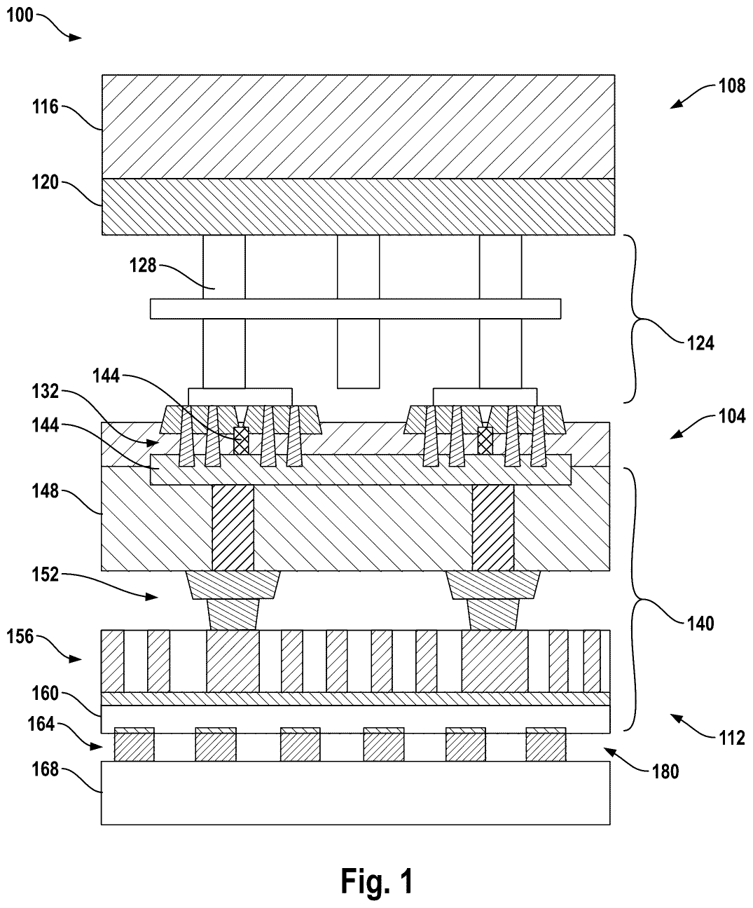

FIG. 1 depicts an integrated circuit 100, for example an integrated circuit (IC), with an improved backside power delivery network (BSPDN) with interconnected cooling channels to promote thermal management of the semiconductor device. The integrated circuit 100 includes a transistor arrangement 104, a front side 108 and a back side 112.

The front side 108 includes a silicon carrier 116 and a bonding interface 120, which are connected to the transistor arrangement 104 via a signal routing arrangement 124 that includes a plurality of signal interconnects 128. The transistor arrangement 104 includes a plurality of transistors 132 connected on the front side to the signal routing arrangement 124.

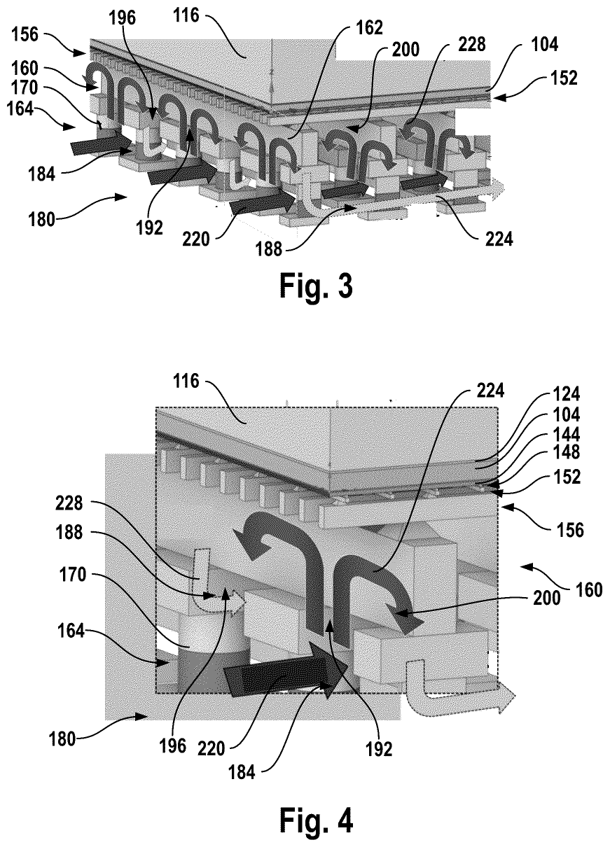

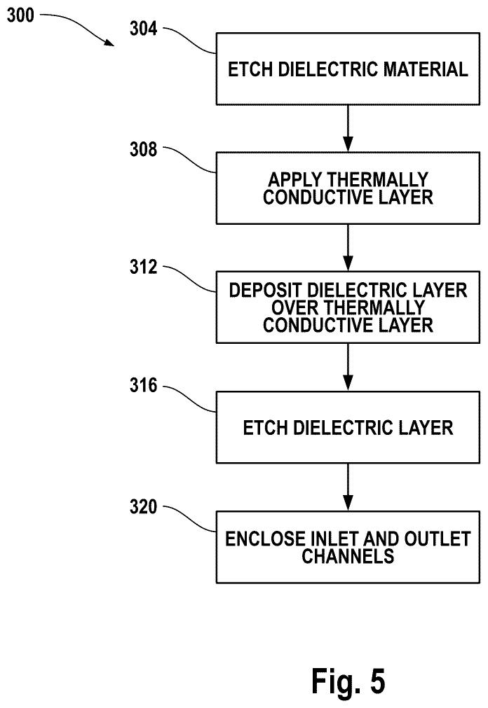

The back side 112 includes a BSPDN 140 that includes a buried power rail 144, a nano-through silicon via (nTSV) layer 148, and a plurality of backside metal (BSM) layers, which include electrical connections to the nTSV layer 148. In the illustrated embodiment, the BSM layers include a BSM1 layer 152, a BSM2 layer 156, and a BSM3 layer 160. A manifold layer 164 connects the BSM3 layer 160 to a power source 168, and may include a plurality of metal connections 170, for example copper-tin-copper bonds or the like, embedded in a dielectric material 172 (not shown in FIGS. 3 and 4 to more clearly show the airflow routing). The power source 168 is therefore electrically connected to the buried power rail 144 and configured to deliver power to the transistor arrangement 104 by a plurality of electrical connections made through the manifold layer 164, the BSM layers 152, 156, 160, and the nTSV layer 148.

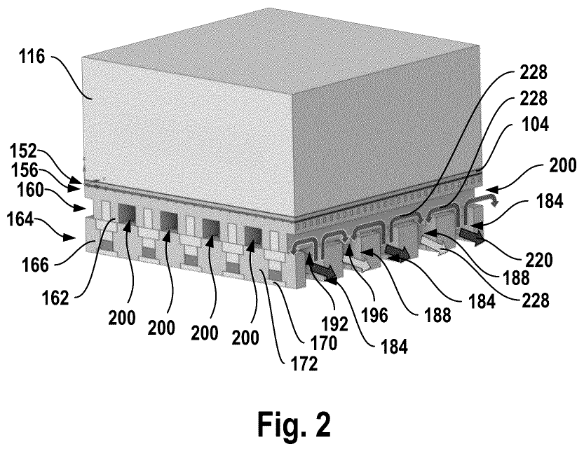

With continuing reference to FIG. 1 and further reference to FIGS. 2-4, the BSPDN 140 and the manifold layer 164 jointly define a cooling arrangement 180 that has a plurality of interconnected channels. FIGS. 2 and 3 depict one embodiment of the cooling arrangement 180. In particular, in the embodiment shown in FIGS. 2 and 3, the cooling arrangement 180 includes a plurality of air inlet channels 184 defined between the structures 166 forming the manifold layer 164 that alternate with a plurality of air outlet channels 188 also defined by the structures 166 forming the manifold layer 164. In particular, the plurality of air inlet channels 184 and the plurality of air outlet channels 188 may be parallel or substantially parallel to one another. The plurality of air inlet channels 184 and plurality of air outlet channels 188 are both connected via respective channel connections 192 and 196 to cooling channels 200 running between the structures 162 forming the BSM3 layer 160. The cooling channels 200 may be parallel or substantially parallel to one another, and may be configured perpendicular or substantially perpendicular to the plurality of air inlet channels 184 and plurality of air outlet channels 188. Each of the plurality of inlet channels 184 is fluidly connected to more than one of the cooling channels 200, and each of the plurality of outlet channels 188 is fluidly connected to more than one of the cooling channels 200. Further, each of the cooling channels 200 is connected to more than one inlet channel 184 and to more than one outlet channel 188. As a result, the inlet channels 184, cooling channels 200, and outlet channels 188 form an interconnected network of channels. In some embodiments, each of the inlet channels 184 may be connected to each of the cooling channels 200, which are in turn connected to each of the outlet channels 188.

The inlet and outlet channels 184, 188 and cooling channels 200 may be formed in any suitable arrangement in one or more of the BSM layers 152, 156, 160 and/or the manifold layer 164. In some embodiments, as in the embodiment illustrated in FIGS. 1-4, the inlet and outlet channels 184, 188 are defined in one or more of the BSM layers 152, 156, 160 while the cooling channels 200 are defined in the manifold layer 164. In other embodiments, at least a portion of the inlet and outlet channels 184, 188 may be formed in one or more of the BSM layers 152, 156, 160, and in one embodiment, the entirety of the inlet and outlet channels and the cooling channels 200 are formed in the BSM layers 152, 156, 160.

The cooling arrangement 180 is configured such that the relatively cold cooling fluid, which can be air or liquid coolant, flows into the manifold layer 164 via the plurality of air inlet channels 184. The cooling fluid then passes into the cooling channels 200 in the BSM3 layer 160 via the respective channel connections 192, shown by arrows 224, where it absorbs heat from the transistor arrangement 104 via the intervening structures (i.e. the nTSV layer 148 and the BSM layers 152, 156).

The microchannel cooling arrangement 180 disclosed herein is designed to provide efficient cooling capable of handling high heat fluxes in excess of, for example, 1 kW/cm². Further, since the microchannels are interconnected, the fluid travel length in the microchannels that have a low hydraulic diameter, specifically the cooling channels, is reduced, resulting in lower pressure drop of the cooling fluid compared to straight microchannels that are not interconnected.

In addition, the manifold layer 164 of the disclosed arrangement, which features alternating inlets and outlets, facilitates vertical routing of fluid by delivering cold cooling fluid from the top and collecting hot fluid through adjacent outlet channels. More specifically, the airflow 220 from each one of the inlet channels 184 diverges into a plurality of flows into the cooling channels 200, and each of these flows diverges into two paths 228, each of which travels through only a short portion of the cooling channels 200 to the adjacent two outlet channels 188. As a result, the flow in the cooling channels 200, which have a lower hydraulic diameter than the inlet and outlet channels 184, 188, is formed by a plurality of relatively short airflow paths 228. Thus, the cooling fluid only traverses a short distance in the cooling channel 200, which reduces pressure drop in the cooling fluid and therefore reduces the energy required to pump the cooling fluid through the cooling arrangement 180.

Further, in some embodiments, the configuration of the cooling channels 200 and the inlet and outlet channels 184, 188 can be modified depending on the desired cooling fluid flow characteristics. For example, in some embodiments, there may be more than one inlet channel between each outlet channel, or more than one outlet channel between each inlet channel. Thus, the configuration of the inlet and outlet channels 184, 188, and the cooling channels 200, is flexible. For example, the inlet and outlet channels 184, 188 may be configured with a central inlet channel 184 surrounded by outlet channels 188 with triangular or hexagonal distributions. In other embodiments, the shapes of the inlet and/or outlet channels 184, 188 may be slotted, concentric, or any other suitable shape.

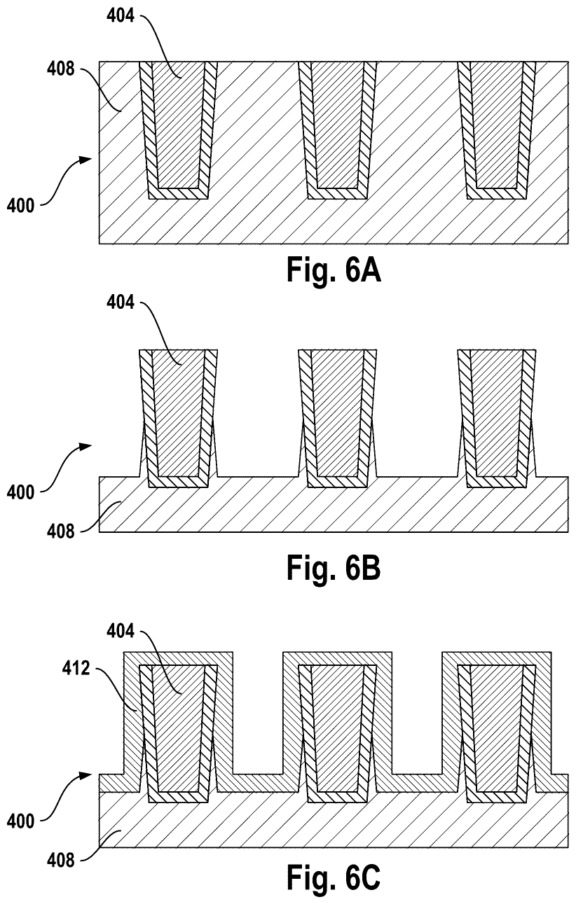

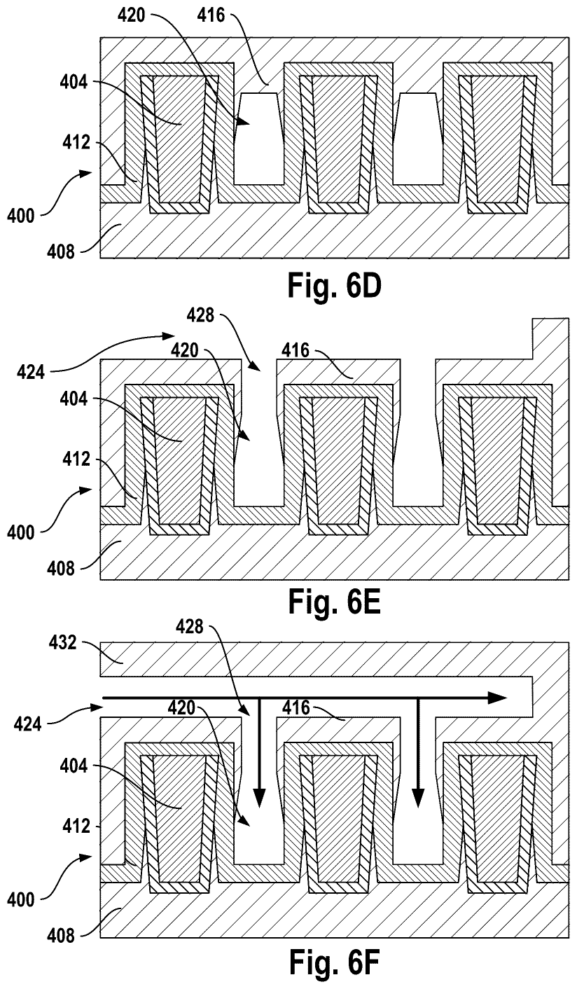

FIG. 5 depicts a process diagram of a method 300 for fabricating a cooling arrangement such as the cooling arrangement 180 described above, while FIGS. 6A-F depict the various stages of the method. In particular, it is noted that the orientation of the BSM3 layer 160 and manifold layer 164 in FIGS. 6A-F is inverted, i.e. upside down, from the view in FIGS. 2-4, such that the BSM3 layer 160 is shown beneath the manifold layer 164.

The method 300 begins as shown in FIG. 6A with a BSM layer 400, which may be the BSM3 layer, but could also be a different layer in the BSM layers, having a plurality of metal structures 404 formed of, for example, copper, embedded in a dielectric material 408 that may be, for example, SiO₂ or Si₃N₄. The method 300 includes etching the dielectric material 408, leaving the metal structures 404 (block 304), as shown in FIG. 6B.

A thin conformal thermally conductive layer 412 is then applied over the plurality of metal structures 404 and the dielectric material 408 (block 308), as shown in FIG. 6C. The thermally conductive layer 412 may be formed of, for example, silicon carbide or another suitable material with high thermal conductivity relative to the dielectric material 408. The thermally conductive layer 412 serves not only for thermal conduction, but also as a barrier protection layer. The thermally conductive layer 412 may be, for example, in a range of from approximately 10 nm to approximately 100 nm, though the thickness of the thermally conductive layer 412 may be smaller or larger depending on the overall dimensions of the cooling arrangement.

The method 300 continues with depositing another dielectric layer 416 over the thermally conductive layer 412, which forms channels 420 between the plurality of metal structures 404 (block 312; see FIG. 6D). The method 300 then proceeds with etching the dielectric layer 416 to form inlet and outlet channels 424 and channel connections 428 between the channels 420 and the inlet and outlet channels 424 (block 316; see FIG. 6E). Finally, an additional dielectric layer 432, along with any metal connections desired in the additional dielectric layer 432, is applied to enclose the inlet and outlet channels 424 (block 320; see FIG. 6F).

It will be appreciated that variants of the above-described and other features and functions, or alternatives thereof, may be desirably combined into many other different systems, applications or methods. Various presently unforeseen or unanticipated alternatives, modifications, variations or improvements may be subsequently made by those skilled in the art that are also intended to be encompassed by the foregoing disclosure.

What is claimed is:

1. An integrated circuit comprising:
a transistor layer;
a backside power delivery network comprising a buried power rail and a plurality of backside metal layers;
a power source electrically connected to the buried power rail by electrical connections in the plurality of backside metal layers; and
a cooling arrangement defined at least partially in the plurality of backside metal layers, the cooling arrangement formed of a plurality of inlet channels, a plurality of outlet channels, and a plurality of cooling channels,
wherein each of the plurality of inlet channels is fluidly connected to a plurality of cooling channels, and each of the plurality of cooling channels is fluidly connected to the plurality of outlet channels.

2. The integrated circuit of claim 1, wherein the plurality of inlet channels alternate with the plurality of outlet channels along a direction defined by the plurality of cooling channels.

3. The integrated circuit of claim 2, wherein the plurality of cooling channels are formed in the plurality of backside metal layers and the plurality of inlet channels and the plurality of outlet channels are formed in a manifold layer interposed between the power source and the plurality of backside metal layers.

4. The integrated circuit of claim 3, wherein the plurality of cooling channels are defined in a layer of the plurality of backside metal layers that is nearest to the power source.

5. The integrated circuit of claim 2, wherein the plurality of cooling channels extend substantially perpendicular to the plurality of inlet channels and the plurality of outlet channels.

6. The integrated circuit of claim 5, wherein each of the plurality of cooling channels is fluidly connected to each of the plurality of inlet channels and to each of the plurality of outlet channels.

7. The integrated circuit of claim 6, wherein the cooling arrangement is configured such that inlet airflow from each of the plurality of inlet channels flows into adjacent outlet channels of the plurality of outlet channels via the plurality of cooling channels.

8. A method of fabricating a cooling arrangement of an integrated circuit comprising:
forming a plurality of cooling channels in at least one backside metal layer of a backside power delivery network of the integrated circuit; and
forming a plurality of inlet and outlet channels, each of which is connected to the plurality of cooling channels.

9. The method of claim 8, wherein the forming of the plurality of cooling channels comprises etching dielectric material around a plurality of metal structures of the backside metal layer.

10. The method of claim 9, wherein the forming of the plurality of cooling channels further comprises applying a thin conformal thermally conductive layer to the plurality of metal structures.

11. The method of claim 10, wherein the forming of the plurality of cooling channels further comprises depositing a dielectric layer over the thermally conductive layer so as to produce the plurality of cooling channels between portions of the thermally conductive layer.

12. The method of claim 11, wherein:
the forming of the plurality of inlet and outlet channels includes etching the dielectric layer to define the plurality of inlet and outlet channels, and
the forming of the plurality of cooling channels further comprises etching the dielectric layer to form channel connections between the plurality of inlet and outlet channels to the plurality of cooling channels.

13. The method of claim 12, wherein the forming of the plurality of inlet and outlet channels includes enclosing the plurality of inlet and outlet channels with a further dielectric layer.

14. The method of claim 11, wherein the dielectric layer deposited over the thermally conductive layer is formed as a manifold layer that connects a power source to the at least one backside metal layer.

15. A cooling arrangement comprising:
a plurality of inlet channels;
a plurality of outlet channels; and
a plurality of cooling channels formed at least partially in a plurality of backside metal layers of a backside power delivery network of an integrated circuit,
wherein each of the plurality of inlet channels is fluidly connected to a plurality of cooling channels, and each of the plurality of cooling channels is fluidly connected to the plurality of outlet channels.

16. The cooling arrangement of claim 15, wherein the plurality of inlet channels and the plurality of outlet channels are defined in a manifold layer that connects a power source to the plurality of backside metal layers.

17. The cooling arrangement of claim 16, wherein the plurality of cooling channels extend substantially perpendicular to the plurality of inlet channels and the plurality of outlet channels.

18. The cooling arrangement of claim 17, wherein each of the plurality of cooling channels is fluidly connected to each of the plurality of inlet channels and to each of the plurality of outlet channels.

19. The cooling arrangement of claim 18, wherein the cooling arrangement is configured such that inlet airflow from each of the plurality of inlet channels flows into adjacent outlet channels of the plurality of outlet channels via the plurality of cooling channels.
